(19) United States
(12) Patent Application Publication
(10) Pub. No.: US 2025/0210454 A1
(43) Pub. Date: Jun. 26, 2025

(54) CONTROL UNIT

(71) Applicant: Robert Bosch GmbH, Stuttgart (DE)

(72) Inventors: Maximilian Amberger, Karlsruhe (DE); Holger Runge, Roesrath (DE); Marius Graf, Kressbronn Am Bodensee (DE); Robert Kornhaas, Spraitbach (DE); Roland Schmidt, Klein Duengen (DE); Susanne Wunderlin, Stuttgart (DE)

(21) Appl. No.: 18/982,185

(22) Filed: Dec. 16, 2024

(30) Foreign Application Priority Data
Dec. 22, 2023 (DE) 10 2023 213 293.1

(51) Int. Cl. H01L 23/427; H01L 23/31

(52) U.S. Cl. CPC H01L 23/427; H01L 23/315

(57) ABSTRACT

Control unit including a housing in which a to-be-cooled electronic unit is provided, wherein at least one space which is at least partially filled with a phase change material is provided in the housing as well.

### CROSS REFERENCE

The present application claims the benefit under 35 U.S.C. § 119 of German Patent Application No. DE 10 2023 213 293.1 filed on Dec. 22, 2023, which is expressly incorporated herein by reference in its entirety.

### FIELD

The present invention relates to a control unit, in particular a control unit for a motor vehicle.

### BACKGROUND INFORMATION

Control units are electronic modules that are used in particular in locations in which equipment or processes are controlled and/or regulated. Control units are used to control machines, systems and other technical processes. Control units are widely used in motor vehicles.

Control units used in motor vehicles are also referred to as automotive control units. Automotive control units configured for automated or highly automated driving can be divided into three categories in terms of their cooling. Devices with a small amount of waste heat, i.e., less than 30 W in the control unit, can be cooled passively via fins, depending on the installation location. Reference is made to FIG. 1. Devices with higher waste heat are cooled via external or internal fans that are guided via cooling fins. For waste heat of around 100 W or more, water-cooled systems are used as well. In this context, reference is made to FIG. 2.

Systems with external water cooling are in focus in particular for highly automated driving functions, because these typically require higher computing power and thus also generate more system waste heat. An additional requirement for these highly automated systems is having to also take into account safety systems that are used to exclude malfunctions or delay them sufficiently; i.e. the critical temperature of the SoC (system-on-chip) is not exceeded within a set period of time.

A typical malfunction for such a system is the failure of the cooling water flow, for example due to a blockage of the coolant pump. For the respective application in automated driving, there should be appropriate measures that ensure that the vehicle can be brought into a safe driving state within a certain period of time, i.e. within a few seconds to half an hour, by the vehicle software on an SoC. Therefore, the SoC of the ADAS unit (ADAS: automated driving and steering: automated driving functions) cannot be switched off or clocked at a lower speed during this period, because full functionality is required until the vehicle is stationary.

One measure is installing materials with a high heat capacity, such as metals. However, both the space and the weight for a control unit (ECU: electronic control unit) are limited. Another option is a redundant cooling path either via a separate pump or via active air cooling. However, both of these are associated with considerable effort and costs. In addition, due to infrequent operation, these active air cooling systems represent new possible points of failure that have to also be addressed with the design.

### SUMMARY

In light of this, according to an example embodiment of the present invention, a control unit is provided. Embodiments will emerge from the disclosure herein.

The presented control unit according to an example embodiment of the present invention comprises a housing in which a to-be-cooled electronic unit is provided. The housing can comprise a control unit front side and a control unit rear side. At least one space which is at least partially, in one embodiment completely, filled with a phase change material (PCM) is provided in the housing as well.

The phase change material (PCM) is a so-called latent heat storage material that can store a high proportion of heat and cold energy over a long period of time and release it again without loss. This makes use of reversible thermodynamic changes in the state of a storage medium, e.g. during the phase transition from solid to liquid.

Until now, the use of PCMs in automotive applications has been limited to use in battery thermal management systems for electric vehicles.

A SoC (system-on-chip) is an integrated circuit in which a large number of functions of a programmable electronic system are implemented. In an SoC, all of the functions are integrated on a semiconductor substrate. A system is understood here to be a combination of different elements which together provide a specific functionality.

In one example embodiment of the present invention, a cost-effective solution for a time-limited heatsink within an ADAS control unit is presented, which can absorb a defined amount of heat for a specific period of time. Ideally, the process is reversible, so that the control unit does not have to be replaced after a coolant failure. In addition, no other actuators, such as pumps, fans, etc., should be installed as another possible point of failure.

In one example embodiment of the present invention, a sufficient amount of PCM material is embedded within a water-cooled ADAS control unit so that the time-limited amount of heat can be buffered by the phase transition.

At least in some embodiments of the present invention, the presented control unit has a number of advantages:

There is the possibility to buffer a time-limited amount of heat without external actuators in such a way that the SoC of the ADAS functions remains fully operable over the entire time in service.

For this solution, there is no need to install redundant external pumps or redundant heat transport systems, such as additional fans, in addition to the water cooling.

PCMs provide 10 to 100 times higher amounts of heat storage in a predefined temperature range than typical construction materials such as metals.

PCMs can be shaped very flexibly and can fill a wide range of cavities in the control unit.

The heat absorption and thus the phase transition of the typical PCMs, such as paraffin, is reversible. This means that it is not absolutely necessary to replace the control unit after such a malfunction and it can remain in use.

Further advantages and embodiments of the present invention will emerge from the disclosure herein.

It goes without saying that the aforementioned features and the features yet to be explained in the following can be used not only in the respectively specified combination, but also in other combinations or on their own, without leaving the scope of the present invention.

### BRIEF DESCRIPTION OF THE DRAWINGS

FIG. 1 shows a schematic illustration of a control unit comprising a passively cooled housing according to the related art.

FIG. 2 shows a schematic illustration of a control unit comprising a water-cooled housing according to the related art.

FIG. 3 shows a schematic illustration of an embodiment of the presented control unit.

FIG. 4 shows a schematic illustration of another embodiment of the presented control unit.

FIG. 5 shows a graph of temperature profiles through blocks made of different materials.

FIG. 6 shows another embodiment of the presented control unit.

FIG. 7 shows yet another embodiment of the presented control unit.

### DETAILED DESCRIPTION OF EXAMPLE EMBODIMENTS

The present invention is illustrated schematically in the figures on the basis of embodiments and is described in detail in the following with reference to the figures.

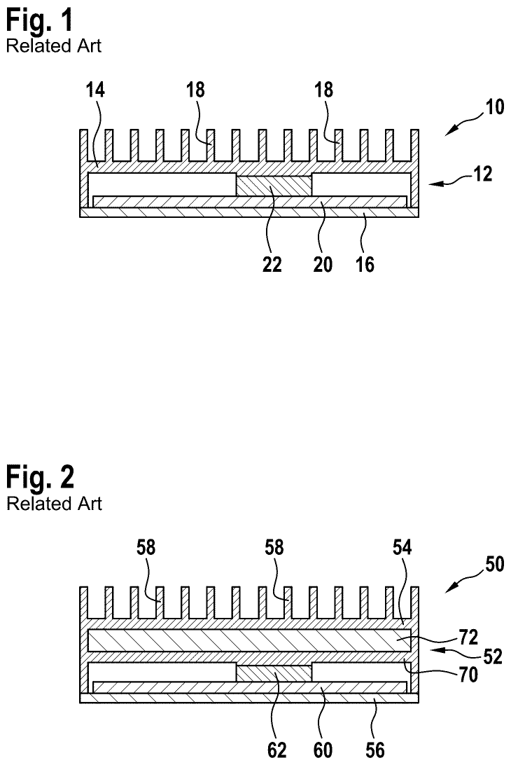

FIG. 1 shows a control unit according to the related art, which is labeled overall with the reference number 10. This control unit 10 comprises a passively cooled housing 12 with a control unit front side 14 and a control unit rear side 16. For cooling, the control unit front side 14 has cooling fins 18. A printed circuit board (PCB) 20 with an SoC 22 disposed upon it is provided in the housing 12. The shown control unit 10 generates only a small amount of waste heat, typically less than 30 W, so that passive cooling with the cooling fins 18 is sufficient.

FIG. 2 shows a control unit 50 comprising a water-cooled housing 52 according to the related art. The housing 52 comprises a control unit front side 54 and a control unit rear side 56. Cooling fins 58 that provide passive cooling are then integrally formed on the control unit front side 54. A printed circuit board 60 and an SoC 62 disposed upon it are provided in the control unit 50 or in the housing 52. A cooling channel 70, in which a cooling liquid 72 is conducted, is also provided in the housing 52 above the SoC 62.

The shown control unit 50 typically generates a waste heat of about 100 W, so that the cooling liquid 72, and in this case consequently water cooling, is used for sufficient cooling. It should also be noted that the external connections are not shown in FIG. 2. The control unit 50 is typically connected to an external cooling circuit.

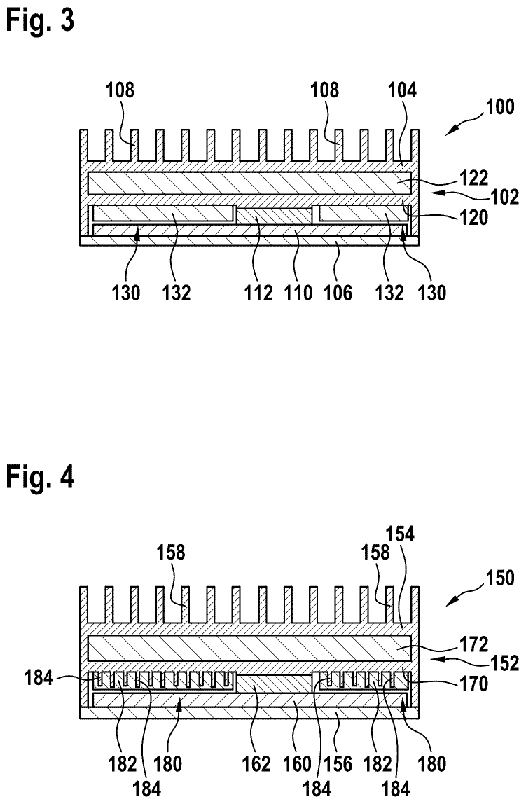

FIG. 3 shows an example embodiment of the presented control unit according to the present invention, which is labeled overall with the reference number 100. The control unit 100 comprises a housing 102, which in turn includes a control unit front side 104 and a control unit rear side 106. Cooling fins 108 that provide passive cooling are integrally formed on the control unit front side 104. A printed circuit board 110 and an SoC 112 disposed upon it are provided in the control unit 100 or in the housing 102. A cooling channel 120, in which a cooling liquid 122 is conducted, is also provided in the housing 102 above the SoC 112.

Two spaces or cavities 130 that are at least partially or completely filled with a phase change material (PCM) 132 are further provided in the control unit 100 on either side of the SoC 112. Since the PCMs can become liquid during use, they are usually encapsulated, in particular microencapsulated. It should also be noted that the external connections are not shown in FIG. 3. The control unit 100 is typically connected to an external cooling circuit.

FIG. 3 illustrates the installation of PCMs 132 in the water-cooled control unit 100, in which case the PCMs 132 are mounted laterally next to the SoC 112. The PCMs 132 absorb the waste heat of the control unit 100 that cannot be dissipated, in particular in the event of a malfunction for an in particular time-limited previously calculated malfunction. The PCMs 132 are furthermore selected such that the phase transition point is outside the operating points of the liquid cooling. With a maximum operating point of 50° C. in the cooling liquid, a PCM 132 with a phase transition temperature of 60° C. is therefore possible.

The spaces 130 and thus the PCM 132 should be disposed in such a way that, in the case of a stationary cooling liquid, the highest possible heat flow is directed into the PCM. This can be achieved with direct mechanical contact between the PCM and the cooling channel in the immediate vicinity of the SoC as shown in FIG. 3. Due to the lower heat flow, the heat then no longer flows through the possibly stationary liquid, but through the metal of the cooling channel 120 into the PCM 132. One way to further increase this heat flow is shown in FIG. 4.

FIG. 4 shows an embodiment of the presented control unit, which is labeled overall with the reference number 150. The control unit 150 comprises a housing 152, which in turn includes a control unit front side 154 and a control unit rear side 156. Cooling fins 158 that provide passive cooling are integrally formed on the control unit front side 154. A printed circuit board 160 and an SoC 162 disposed upon it are provided in the control unit 150 or in the housing 152. A cooling channel 170, in which a cooling liquid 172 is conducted, is also provided in the housing 152 above the SoC 162.

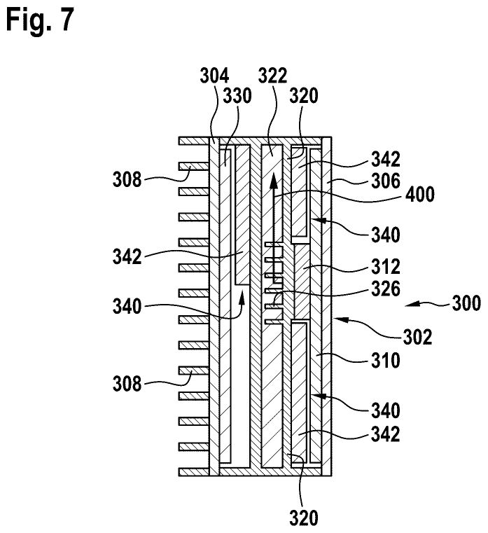

Two spaces 180 that are at least partially or completely filled with a phase change material (PCM) 182 are further provided in the control unit 150 on either side of the SoC 162. It should also be noted that the external connections are not shown in FIG. 4. The control unit 150 is typically connected to an external cooling circuit. This also applies to the further embodiments of FIGS. 6 and 7.

According to FIG. 4, small metallic cooling fins 184 project into the PCM 182 and thus significantly increase the heat transport into the spaces 180 filled with PCM 182. Care must be taken to ensure the metal-to-PCM ratio. This design is primarily due to the low thermal conductivity of typical PCMs, such as paraffin. These cooling fins 184 can also be provided in the embodiments of FIGS. 6 and 7.

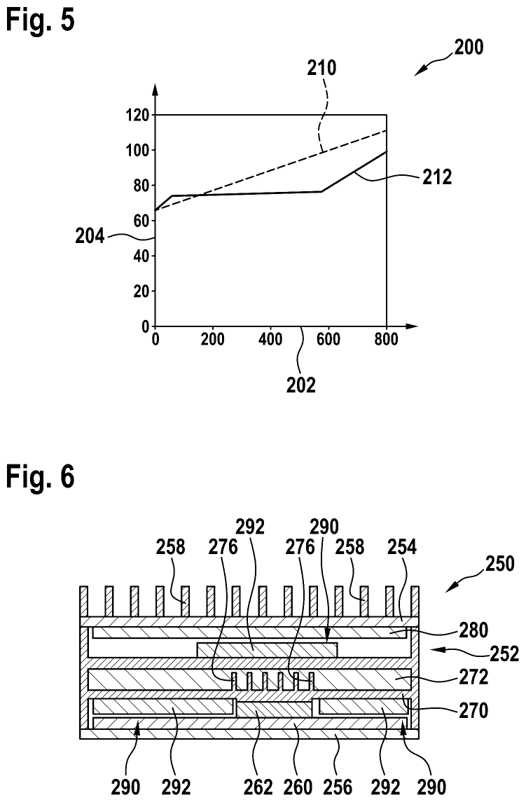

FIG. 5 shows the mode of action of the PCM in comparison with a heatsink. FIG. 5 shows a graph 200, on the abscissa 202 of which the time(s) is plotted and on the ordinate 204 of which the temperature (C) is plotted. A first curve 210 shows the temperature profile for a copper block weighing 4, 567 g and a second curve 212 shows the temperature profile for a PCM block weighing 410 g.

According to FIG. 5, the same amount of heat flow is passed through cubes of PCM or copper that are the same size but not the same weight. The PCM in this simulation has a phase transition temperature of approximately 70° C. The phase transition temperature of the material can therefore be seen at approximately 70° C., at which the PCM keeps the temperature almost constant for a very long time. It can also be seen that, with the same volume and a time-limited cooling time, significant weight savings are possible with the use of PCM.

The PCM can be installed at any location in the control unit at which such high heat flow occurs in the event of a malfunction that the critical temperatures in the SoC, for example for the electronic unit, are not exceeded. This varies depending on the design of the control unit, but some specific installation locations can be identified across all variants.

FIG. 6 shows an embodiment of the presented control unit, which is labeled overall with the reference number 250. The control unit 250 comprises a housing 252, which in turn includes a control unit front side 254 and a control unit rear side 156.

Cooling fins 258 that provide passive cooling are integrally formed on the control unit front side 254. A first printed circuit board 260 and an SoC 262 disposed upon it are provided in the control unit 250 or in the housing 252. A cooling channel 270, in which a cooling liquid 272 is conducted and from which cooling fins 276 project into the cooling liquid 272, is also provided in the housing 252 above the SoC 262. A second printed circuit board 280 is disposed in the housing 252 on the control unit front side 254 as well.

The illustration also shows three spaces 290 that are filled with PCM 292. Of these, two are disposed on either side of the SoC 262 and one is disposed above the cooling channel 270. The control unit 250 thus comprises the cooling channel 270 with the PCM 292 on top. The cooling liquid 272 heats the upper side of the cooling channel 270 and thus the PCM 292 by its own convection.

A basic variant is to install the PCM directly above the SoC. This is useful in particular for horizontally installed control units, because the warm cooling liquid that rises due to natural convection heats the upper side of the cooling channel 270 and thus the control unit 250. An appropriate amount of PCM can be placed there depending on the thermal conductivity of the material of the cooling channel 270 and the material thickness.

The internal cooling fins 276 can additionally ensure that the heat transfer is particularly efficient here and that the thermal resistance to the opposite side is as low as possible.

An alternative design is to install the control unit and circuit board vertically as shown in FIG. 7.

FIG. 7 shows another embodiment of the presented control unit, which is labeled overall with the reference number 300. The control unit 300 comprises a housing 302, which in turn includes a control unit front side 304 and a control unit rear side 306. Cooling fins 308 that provide passive cooling are integrally formed on the control unit front side 304. A first printed circuit board 310 and an SoC 312 disposed upon it are provided in the control unit 300 or in the housing 302. A cooling channel 320, in which a cooling liquid 322 is conducted and from which cooling fins 326 project into the cooling liquid 322, is also provided in the housing 302 above the SoC 312. A second printed circuit board 330 is disposed in the housing 302 on the control unit front side 304 as well.

The illustration also shows three spaces 340 that are filled with PCM 342. Of these, two are disposed on either side of the SoC 312 and one is disposed above the cooling channel 320.

In this case, the heat flows upward (arrow 400) within the cooling channel 320, so that the PCMs 342 should be mounted above on either side of the cooling channel 320. Below the heat source, the SoC 312, on the other hand, no major amount of heat flow is to be expected.

There are different installation variants for the PCM depending on the orientation of the control unit and the installation location of the to-be-cooled components. The shown variants represent only a fraction of the possible installation options. Common to all is the operating principle of using PCMs to buffer a limited amount of heat, in particular in the emergency mode of the control unit.

The proposed approach is suitable in particular for water-cooled control units and especially for control units for which there are extended safety requirements in the event of a malfunction.

What is claimed is:

1. A control unit, comprising:
a housing in which a to-be-cooled electronic unit is provided, wherein at least one space which is at least partially filled with a phase change material is provided in the housing.

2. The control unit according to claim 1, wherein at least one cooling channel for conducting a cooling medium is provided in the housing.

3. The control unit according to claim 2, wherein the cooling medium is a cooling liquid.

4. The control unit according to claim 2, wherein there is direct contact between at least one space of the at least one space and at least one cooling channel and the at least one cooling channel.

5. The control unit according to claim 4, wherein the at least one cooling channel has cooling fins that project into the at least one space.

6. The control unit according to claim 3, wherein the phase change material of at least one space is selected such that the phase transition point is outside the operating points of the liquid cooling system created by the cooling channel and the cooling liquid.

7. The control unit according to claim 1, wherein at least one space of the at least one space is disposed in a region of the electronic unit.

8. The control unit according to claim 6, wherein there is a space on either side of the electronic unit.

9. The control unit according to claim 1, wherein the electronic unit is configured as a system-on-chip (SoC).

10. The control unit according to claim 1, wherein at least one space of the at least one space is encapsulated.

11. The control unit according to claim 1, wherein at least one space of the at least one space is installed at a location at which such high heat flow occurs in an event of a malfunction that the critical temperatures in an SoC are not exceeded.
